(19) United States
(12) Patent Application Publication
(10) Pub. No.: US 2017/0200587 A1
(43) Pub. Date: Jul. 13, 2017

(54) ATOMIC LAYER ETCHING SYSTEM WITH REMOTE PLASMA SOURCE AND DC ELECTRODE

(71) Applicant: Applied Materials, Inc., Santa Clara, CA (US)

(72) Inventors: Ludovic GODET, Sunnyvale, CA (US); Jun XUE, San Jose, CA (US); Sang Ki NAM, Danville, CA (US)

(21) Appl. No.: 15/399,084

(22) Filed: Jan. 5, 2017

Related U.S. Application Data
(60) Provisional application No. 62/276,098, filed on Jan. 7, 2016.

(51) Int. Cl. H01J 37/32; H01L 21/3065

(52) U.S. Cl. CPC H01J 37/32082; H01J 37/32532; H01J 37/3244; H01L 21/3065; H01J 2237/334

(57) ABSTRACT

Implementations described herein relate to apparatus and methods for performing atomic layer etching (ALE). Pulsed plasma generation and subsequent bias application to plasma afterglow may provide for improved ALE characteristics. Apparatus described herein provide for plasma generation from one or more plasma sources and biasing of plasma afterglow to facilitate material removal from a substrate.

### CROSS-REFERENCE TO RELATED APPLICATIONS

This application claims benefit of U.S. Provisional Patent Application No. 62/276,098, filed Jan. 7, 2016, the entirety of which is herein incorporated by reference.

### BACKGROUND

Field

Implementations of the present disclosure generally relate to an atomic layer etching apparatus.

Description of the Related Art

Moore's law and the continued development of semiconductors predict that devices in future integrated circuits will be as small as one atomic layer thick and less than several atomic layers wide. Present plasma etching processes are generally unable to achieve precise pattern transfer for advanced technology nodes. These current etching techniques may also damage underlying layers of a substrate. In particular, traditional plasma etching techniques lack the level of control that is needed for precise patterning of sub-20 nm structure and current atomic layer etching with pulsed gases is too slow to be practical for large volume manufacturing of integrated circuits.

Atomic layer etching (ALE) has been developed as a promising etch technology for advanced technology nodes. ALE generally includes four operations. First, a chemisorption operation, including clean substrate exposure to a reactant gas to facilitate the adsorption of the reactant gas onto the substrate surface. Second, excess Cl₂ gas is purged with an inert gas flow to avoid etching by a gas-phase reactant in the subsequent step. Third, the reaction step, such as chemical sputtering, is affected between the adsorbed gas and the underlying solid reaction, often via inert gas plasma. This process may also be self-limiting in that ions react only with substrate atoms bonded to the chemisorbed gas.

Once the chlorinated layer is removed, further etching by physical sputtering of the substrate is significantly reduced or eliminated. Finally, evacuation of a reaction chamber is utilized to exhausts the etching byproducts. If the periods of chemisorption in the first operation and the etching third operation are for sufficiently extended durations, the etching rate approaches one atomic layer per cycle, where the atomic layer thickness is that of the chlorinated layer, but not necessarily one monolayer of the substrate. Additionally, if the substrate surface remains nearly-atomically smooth during the ALE cycling, it is possible to achieve ideal removal conditions of substantially one monolayer of the substrate per cycle.

Recent developments to ALE have further improved etching performance. For example, constant gas flows and the like have improved the etch rate to achieve potentially commercially viable ALE etching processes. However, problems still exist even with new ALE advancements. For example, photo-assisted etching (PAE) is a phenomenon in which undesirable additional etching of the substrate or degradation of a photoresist occurs as a result of photons emitted from the plasma being utilized to perform the ALE process. As such, undesirable microtrenches may be formed upon exposure to the photons which may reduce device yield or contribute to device failure at advanced technology nodes.

Accordingly, what is needed in the art are improved apparatus for ALE processes.

### SUMMARY

In one implementation, a processing chamber apparatus is provided. The apparatus includes a plate stack configured to generate a first plasma, a substrate support assembly disposed opposite the plate stack, and a process region defined between the plate stack and the substrate support assembly. The process region may be configured to maintain generation of a second plasma and a remote plasma source may also be fluidly coupled to the process region.

In another implementation, a processing chamber apparatus is provided. The apparatus includes a plate stack configured to generate a first plasma and the plate stack includes a first diffuser, a faceplate, a ceramic ring, a second diffuser, a gas distribution device, and a plasma blocking screen. A substrate support assembly is disposed opposite the plate stack and a process region defined between the plate stack and the substrate support assembly is configured to maintain generation of a second plasma. A remote plasma source is also fluidly coupled to the process region.

In yet another implementation, a processing chamber apparatus is provided. The apparatus includes a plate stack configured to generate a first plasma and the plate stack includes a first diffuser, a faceplate, a ceramic ring, a second diffuser, a gas distribution device, and a plasma blocking screen. An RF electrode is electrically coupled to the first diffuser and the faceplate and the first plasma is a remote plasma generated between the faceplate and the second diffuser. A substrate support assembly is disposed opposite the plate stack and a process region, configured to maintain generation of a second plasma, is defined between the plate stack and the substrate support assembly.

### BRIEF DESCRIPTION OF THE DRAWINGS

So that the manner in which the above recited features of the present disclosure can be understood in detail, a more particular description of the disclosure, briefly summarized above, may be had by reference to implementations, some of which are illustrated in the appended drawings. It is to be noted, however, that the appended drawings illustrate only exemplary implementations and are therefore not to be considered limiting of its scope, may admit to other equally effective implementations.

FIG. 1 illustrates a method of performing an atomic layer etching process, according to implementations described herein.

FIG. 2 illustrates a schematic, cross-sectional view of a processing chamber, according to implementations described herein.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Implementations described herein relate to apparatus and methods for performing atomic layer etching (ALE). Pulsed plasma generation and subsequent bias application to plasma afterglow may provide for improved ALE characteristics. Apparatus described herein provide for plasma generation from one or more plasma sources and biasing of plasma afterglow to facilitate material removal from a substrate.

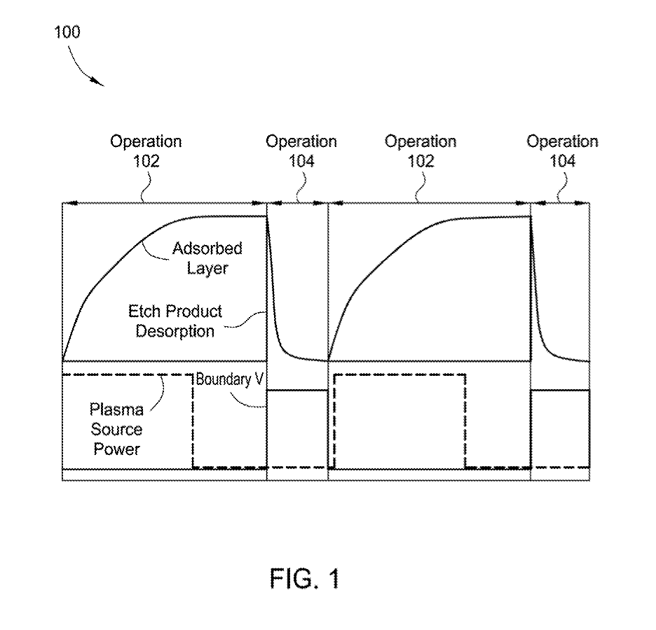

FIG. 1 illustrates an atomic layer etching (ALE) process 100 according to an implementation of the present disclosure. The top portion of the FIG. 1 illustrates the ALE process 100, whereas the bottom portion of the FIG. 1 illustrates the process parameter. The ALE process 100 includes two operations: an adsorption operation 102 and an etching operation 104. During the adsorption operation 102, a substrate may be exposed to adsorbate such that the adsorbate may adsorb onto the surface of the substrate. In some implementations, the adsorbate may be a reactant. For example, the adsorbate may include dissociated reactant atoms or dissociated reactant molecules having unpaired electrons or dangling bonds. The reactant may include, without limitation, halogens, such as fluorine (F), chlorine (Cl), bromine (Br), or iodine (I). Non-halogen materials, such as hydrogen (H₂) and oxygen (O₂) may also be utilized in certain implementations. In one implementation, the reactant may be disassociated chlorine (CI) atoms that are derived from chlorine reactant gas (Cl₂). It is contemplated that other halogens, halogenated species, or other reactants may also be used in the adsorbate. In alternate implementations, the intact or un-dissociated reactant may also be used as the adsorbate on the substrate. Suitable adsorbate precursors include, without limitation, CF₄, CHF₃, BlO₃, Bl₃, BCl₃, H₂, and O₂, among others. As utilized herein, the term “gas” includes vapor generated from a substance in solid or liquid state at room temperature or at standard temperature and pressure, without limitation.

The adsorbate may be obtained by generating plasma containing the reactants. In one implementation, inert gas may be ionized along with the reactant. Without limitation, the resulting plasma may contain reactants, reactant gas ions, and inert gas ions. In one implementation, argon (Ar) is utilized as the inert gas. It is contemplated that any noble gas species or other inert gas species may also be utilized.

In certain implementations, if the reactant is ionized with the inert gas, the concentration of the reactant gas, may be between about 0.01% and about 20% by volume; alternatively, the reactant gas concentration may be between about 0.01% and about 15%; and in certain implementations, the reactant gas concentration may be between about 0.01% and about 10% by volume of the combined gas. In one implementation, the reactant gas may include a concentration of less than about 1% by volume. Without limitation, the plasma generated may include Ar species and a small portion of CI reactant gas species.

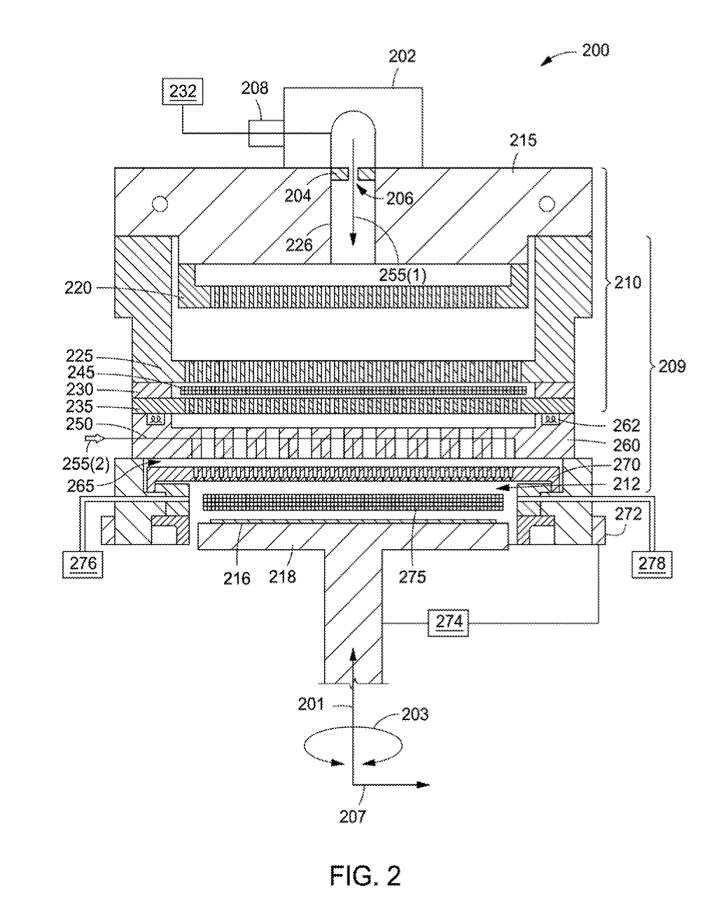

In certain implementations, a plasma source is used to generate the reactant. Non-limiting exemplary plasma sources may include, inductively coupled plasma (ICP) sources, capacitively coupled plasma (CCP) sources, helicon sources, microwave sources, and remote plasma sources (RPS). In certain implementations, the plasma source is a remote plasma source. In operation, the remote plasma source may RF powered during the adsorption operation 102. Suitable apparatus for performing the method 100 is described in greater detail with regard to FIG. 2.

In certain implementations, the plasma source is not powered through the entire adsorption operation 102. For example, the RF power applied to the plasma source may be lowered during the latter portion of the adsorption stage 102. In non-limiting examples, the plasma source may be RF powered during the beginning portion of the adsorption operation 102. During the latter portion of the operation 102, lower power may be applied to the plasma source, or the plasma source may be turned OFF to provide afterglow. Alternatively, the plasma source may be powered continuously throughout the entire adsorption operation 102.

Without intending to be bound by theory, the adsorption process may occur as described herein. A substrate comprising a clean surface, without a passivating layer may include unpaired electron or dangling bonds. Reactants from the plasma near the substrate surface may then bond with the dangling bonds of the surface, such as through chemisorption, to form a product layer. For example, the product layer may comprise a monolayer of the reactants and a monolayer of the substrate atoms that are associated. More specifically, the Cl reactants are adsorbed onto the surface of an exemplary silicon (Si) substrate to form a product layer comprising SiClₓ, where x is between 1 and 4 and the product layer may include known products and ionic species. Further, in certain instances, the product layer may comprise a monolayer of reactant species CI atoms and a monolayer of Si atoms. Adsorption may continue until the substrate surface is saturated with the reactants. Without limitation, saturation is achieved when substantially all available substrate surface-sites, such as unpaired electrons or dangling bonds, are occupied or associated with the reactants. In certain instances a portion of the substrate surface is not covered with the reactants. For example, a portion of the substrate surface may contain a passivating layer, such as but not limited to an oxide layer. In non-limiting examples, the passivating layer may not contain available sites, available unpaired electrons or dangling bonds, and as such is not covered with the reactants. In certain implementations, the substrate surface is at least partially covered with chemisorbed reactants in the product layer and at least partially covered with a passivating layer.

In certain implementations, during the adsorption operation 102, the reactant gas ions and/or inert gas ions may be present in the plasma, such that the substrate surface comprising a product layer is exposed to the ions. The energy of the ions (i.e. plasma potential) bombarding the substrate may be selectively controlled to avoid or minimize undesired etching, physical, or chemical sputtering. For example, the energy required by Cl ions to etch Si may be less than about 25 eV, whereas the energy required by Ar ions to cause sputtering may be between about 30 eV and about 60 eV. In certain implementations, the energy of the ions bombarding the substrate during the adsorption operation 102 may be controlled to be about 15 eV or less. The ion energy may be controlled by, for example, providing an electrostatic shielding (e.g. Faraday shield) of the plasma source and/or performing the process under relatively high pressure, for example, less than about 50 mTorr, in order to minimize undesired etching, physical, or chemical sputtering.

After completion of the adsorption operation 102, the etching operation 104 may be performed. During the etching operation 104, ions may bombard the substrate to remove the product layer. In certain implementations, the ions include positively charged ions or negatively charged ions. In one implementation, positively charged ions are used to remove the product layer. It is contemplated that the energy of the ions bombarding the substrate during the etching operation 104 may preferably be above the threshold for chemically-assisted sputtering but below the threshold for physical sputtering. The ions with selected energy may be directed toward the substrate by controlling the potential difference between the plasma and the substrate. To direct positive ions toward the substrate, the potential difference between may be increased by increasing the plasma potential relative to the substrate potential, decreasing the substrate potential relative to the plasma, or both. To direct negative ions, the potential difference between may be increased by decreasing the plasma potential relative to the substrate potential, increasing the substrate potential relative to the plasma, or both. Positive or negative, DC or RF bias may be applied to the plasma and/or the substrate during the etching operation 104. In addition, continuous bias may be provided to the plasma and/or the substrate. Alternatively, a series of pulsed bias may also be utilized. In pulsed bias implementations, DC bias may be applied for an amount of time between about 10 μs (10 microseconds) and about 500 μs.

In certain implementations, the plasma source may be RF powered during the etching operation 104. For example, the plasma source may be provided with pulsed RF power, where each RF power pulse is provided between the bias pulses noted above. In certain implementations, the RF power pulse may be applied for an amount of time between about 50 μs and about 200 μs. As such, a series of pulsed RF power may be applied to the plasma source during the etching operation 104 and a series of pulsed DC or RF bias may be applied to the plasma and/or the substrate. Each bias pulse may be provided between the RF power pulses. The bias pulse may be delayed for an amount of time between about 20 μs and about 200 μs after ceasing of the RF power pulse. In other words, the bias pulse may be delayed and then initiated during the plasma afterglow.

By selectively increasing the potential difference between the plasma and the substrate, the product layer, which includes the chlorinated product layer in the certain implementation described here, may be removed. In the process, the monolayer of the substrate atoms associated with the product may be removed from the substrate concurrently. Additionally, the adsorption operation 102 and the etching operation 104 may be repeated to remove additional layers of the substrate atoms one layer at a time.

FIG. 2 illustrates a schematic, cross-sectional view of a processing chamber 200 according to implementations described herein. The processing chamber 200 includes a first plasma source 210 and a process region 212 that may also generate or contain a remotely generated plasma during various processing operations, as discussed below. In the orientation of FIG. 2, a general direction of gas and/or plasma product flow is downwards (i.e. towards a substrate support assembly 218), and this direction may be referred to as “downstream” herein, while an opposing direction upwards in the orientation of FIG. 2, may be referred to as “upstream.” Gas and/or plasma products which flow along a radial direction 207 may be referred to as “cross-flow” herein. Also, significant portions of the apparatus shown in FIG. 2 may be cylindrically symmetric about a central axis 201, with associated directions being defined as the radial direction 207 and an azimuthal direction 203. This convention of directions may be used herein, although one skilled in the art will understand that many of the principles described herein are not limited to cylindrically symmetric systems.

As shown in FIG. 2, the first plasma source 210 may introduce gases, and/or gases that are ionized by an upstream remote plasma source, as plasma source gases 255(1), through an RF electrode 215. In certain implementations, the plasma source gases 255(1) may be any of the inert gases described above with regard to FIG. 1. A gas manifold 202 may be coupled to and/or disposed adjacent the RF electrode 215. Process gasses may be provided to the gas manifold 202 from a gas first source 232. The process gases from the first gas source 232 may enter the gas manifold 202 through a feed-through member 208. In one implementation, the feed-through member 208 may be formed from a polymeric material, such as polytetrafluoroethylene. A flow centering insert 204 may be disposed within a gas inlet tube 226 adjacent the gas manifold 202. The flow centering insert 204 may be a ring like apparatus with an opening 206 formed therein. The opening 206 may be formed through the center of the insert 204 and the opening 206 may be a single aperture or may be multiple apertures. In the single aperture implementation, a diameter of the opening 206 may be about 0.125 inches. The flow centering insert 204 may improve concentric flow distribution of process gases within the processing chamber 200.

The RF electrode 215 may be electrically coupled to a first gas diffuser 220 and a face plate 225 that serve to redirect flow of the source gases so that gas flow is uniform across the first plasma source 210 (uniform from left to right in the view of FIG. 2). It should be noted that all of the diffusers or screens described hereinafter may be characterized as electrodes, as any such diffusers or screens may be tied to a particular electrical potential. An insulator 230 electrically insulates the RF electrode 215, including the face plate 225, from a second diffuser 235 that is held at electrical ground. The second diffuser 235 serves as a second electrode counterfacing the face plate 225 of the RF electrode 215.

Surfaces of the face plate 225, the second diffuser 235 and the insulator 230 define a first plasma generation cavity where a first plasma 245 (i.e. first remote plasma) may be created when the plasma source gases are present and RF energy is provided at the face plate 225 through the RF electrode 215. The RF electrode 215, the face plate 225, and the second diffuser 235 may be formed of any conductor, and in implementations are formed of aluminum (or an aluminum alloy, such as the known “6061” alloy type).

Surfaces of the face plate 225 and the second diffuser 235 that face the first plasma 245 directly may be coated with ceramic layers of, for example, yttria (Y₂O₃) or alumina (Al₂O₃) for resistance to bombardment by energetic plasma products generated in the plasma 245. The ceramic coating may be formed by an electron beam coating process, an anodization process, and/or a non-pore anodization process. Other suitable coatings include nickel plated coatings and surface oxidation processes, for example, by exposure to a concentrated HNO₃ solution. Other surfaces of the face plate 225 and the second diffuser 235 that are not necessarily exposed directly to plasma, but are exposed to reactive gases and/or radicals generated by plasmas, may be coated either with ceramic layers (e.g., yttria, alumina) or with a suitable passivating layer (e.g., an anodized layer, or a chemically generated alumina layer) for chemical resistance. The insulator 230 may be any insulator, and in certain implementations, is formed from a ceramic material.

Plasma products generated in the first plasma 245 pass through the second diffuser 235 that again helps to promote the uniform distribution of plasma products, and may assist in electron temperature control. Upon passing through the second diffuser 235, the plasma products pass through a gas distribution device 260 that promotes uniformity. The gas distribution device 260 is also held at electrical ground. Apertures that pass completely through the gas distribution device 260 are generally of a diameter at least three times a diameter of apertures within the second diffuser 235. Also, the gas distribution device 260 includes further gas channels 250 that may be used to introduce one or more gases 255(2) to the plasma products as they enter the process region 212 (that is, gases 255(2) emerge only from a side of gas distribution device 260 that is distal to second diffuser 235). The gases 255(2) may be provided from a second gas source (not shown). In certain implementations, the gases 255(2) may be adsorbate or reactant gases as described with regard to FIG. 1. The gas distribution device 260 may also be made of aluminum or aluminum alloy, and like the face plate 225 and the second diffuser 235 discussed above, may be at least coated with a passivating layer for chemical resistance, or may be coated with a ceramic layer.

A heating element 262 may also be disposed in the processing chamber 200. The heating element 262 may be a spiral shaped heater, such as a resistive heater or the like. The heating element 262 may be disposed in a groove formed in the gas distribution device 260 as illustrated, or may be disposed in groove formed in the second diffuser 235. Alternatively, the heating element 262 may be disposed in a groove formed in the gas distribution device 260 facing a plasma blocking screen 270. In another implementation, the heating element 262 may be disposed in a groove formed in the plasma blocking screen 270 facing the gas distribution device 260. The heating element 262 may be configured to improve symmetric thermal distribution across the processing chamber 200 and facilitate maintenance of the first plasma 245 and/or plasma products (i.e. radicals). In general, each of the plates, diffusers, and/or showerheads 220, 225, 230, 235, 260, 270 may be collectively referred to as a plate stack 209. The plate stack 209 is generally disposed within the processing chamber 200 between the RF electrode 215 and opposite the substrate support assembly 218.

The gases 255(1), 255(2) and/or plasma products from the first plasma 245 enter a plenum cavity 265, then pass through the plasma blocking screen 270 to the process region 212. The plasma blocking screen 270 may have a thickness in the range of between about 0.01 inches and about 1.0 inch, and many small apertures that are configured to allow gases and plasma products from upstream sources pass through into the process region 212 may be formed therein. The apertures of the plasma blocking screen 270 are generally high aspect ratio holes and a hole diameter of the apertures may be between about 0.01 inches and about 0.25 inches. The plasma blocking screen 270 substantially blocks downstream plasmas and plasma products from upstream components, as discussed in detail below. In implementations, the plasma blocking screen 270 may advantageously form at least ten apertures per square inch in a central region thereof, and in certain implementations may form thirty or more apertures per square inch. In one implementation, the plasma blocking screen may be disposed a distance of between about 0.5 cm and about 4 cm from the substrate support assembly 218 when the substrate support assembly 218 is disposed in a processing position. The relatively small distance between the plasma blocking screen 270 and the substrate support assembly 218 reduces the volume of the process region 212. By reducing the volume of the process region 212, processes performed in the processing chamber 200 may be performed more economically and processing conditions of the process regions 212 may be changed more efficiently and quickly.

Like the gas distribution device 260, the plasma blocking screen 270 is also held at electrical ground. Like the face plate 225 and the second diffuser 235 discussed above, surfaces of the plasma blocking screen 270 that are exposed directly to plasma are advantageously coated with ceramic (e.g., alumina or yttria) while surfaces that are not exposed directly to plasma may also be coated with ceramic, and are advantageously at least coated with a passivating layer for chemical resistance to reactive gases and activated species. In one implementation, a detachable coating containing a silicon material may be disposed on the plasma blocking screen 270 to reduce defectivity and enable efficient replacement of the coating if the coating becomes damaged or operates with reduced efficiency.

All of the gases and/or plasma products, generated as described above, interact with a substrate 216 which may be disposed within the process region 212, and a second plasma 275 (i.e. direct plasma) may be generated within the process region 212. When a plasma is desired within process region 212, because the second diffuser 235 is held at electrical ground, RF power to create the second plasma 275 is applied to the substrate support assembly 218. Depending on the flow of gases, adsorbate/reactant or inert gas plasmas may be generated as the second plasma 275. It is contemplated that alternating the flow of adsorbate/reactant gases and inert gases, and subsequent plasma generation may enable the method 100. In one implementation, the first plasma 245 may comprise an inert gas plasma and the second plasma 275 may comprise an adsorbate/reactant gas plasma.

A DC bias may also be applied to the substrate support assembly 218 to steer ions generated in the first or second plasmas 245, 275 to facilitate directional (anisotropic) ALE of the substrate 216. The substrate support assembly 218 may also include an electrostatic chuck to secure the substrate 216 thereon during processing. In another implementation, a bias ring 272 may be coupled to the processing chamber 200 adjacent the substrate support assembly 218. The bias ring 272 may made from any material in any geometric shape which provides biasing of a plasma or plasma afterglow towards the substrate 216 disposed in the process region 212. The substrate support assembly 218 and/or bias ring 272 may be switchably connected with an RF and/or DC bias source 274, so as to generate a plasma and/or bias potential within process region 212 at selected times and not at other times. The substrate support assembly 218 may be connected with the same RF power supply as is used to create the first plasma 245 between the face plate 225 and the second diffuser 235, or may be connected with a different RF power supply.

In certain implementations, a remote plasma source 276 may be fluidly coupled with the process region 212. Although not illustrated, the remote plasma source 276 may be coupled to a third gas source (or the second gas source depending upon the desired type of plasma to be generated). In this implementation, a third plasma may be generated remotely from the process region 212 and delivered to the process region 212. For purposes of illustration, the third plasma (generated in the remote plasma source 276) may occupy the same area as the second plasma 275. However, the third plasma may be cross-flowed along the radial direction 207 through the process region 212 to an exhaust which is fluidly coupled to the process region 212. In one implementation, the exhaust 278 may be coupled to the process region 212 opposite the remote plasma source 276. In one implementation, adsorbate/reactant gases may be remotely generated into the third plasma and delivered to the process region 212. In one implementation, both the second plasma 275 and the third plasma generated by the remote plasma source 276 may be utilized to generate the adsorbate/reactant plasma or plasma products. Alternatively, one of the second plasma 275 or the third plasma generated by the remote plasma source 276 may be utilized to generate the adsorbate/reactant plasma or plasma products.

In operation, the substrate support assembly 218 may be rotated during exposure of the substrate 216 to the third plasma/plasma products to improve exposure uniformity and substrate surface active site reactions with the adsorbate/reactant plasma and/or plasma products. It is believed that by generating the adsorbate/reactant plasma or plasma products remotely from the process region 212, undesirable photo assisted etching (PAE) may be reduced or eliminated. It is contemplated that remote plasma generation may reduce or eliminate the presence of photons present in the third plasma or plasma products “seen” by the substrate 216 in the process region 212. Accordingly, ALE processes may be enabled without the deleterious effects of PAE.

While the foregoing is directed to implementations of the present disclosure, other and further implementations of the disclosure may be devised without departing from the basic scope thereof, and the scope thereof is determined by the claims that follow.

1. A processing chamber apparatus, comprising:
a plate stack configured to generate a first plasma;
a substrate support assembly disposed opposite the plate stack;
a process region defined between the plate stack and the substrate support assembly, wherein the process region is configured to maintain generation of a second plasma; and
a remote plasma source fluidly coupled to the process region to provide a cross-flow of plasma products through the process region.

2. The apparatus of claim 1, further comprising:
an RF electrode;
a gas source;
a gas manifold; and
a gas inlet tube.

3. The apparatus of claim 2, wherein a flow centering insert is disposed within the gas inlet tube adjacent the gas manifold.

4. The apparatus of claim 2, wherein the gas source is configured to deliver an inert gas to the plate stack.

5. The apparatus of claim 1, wherein the plate stack comprises:
a first diffuser;
a faceplate;
a ceramic ring;
a second diffuser;
a gas distribution device; and
a plasma blocking screen.

6. The apparatus of claim 5, wherein the faceplate and the second diffuser define a remote plasma region.

7. The apparatus of claim 5, wherein each of the first diffuser, the faceplate, the ceramic ring, the second diffuse, the gas distribution device, and the plasma blocking screen are coated with a ceramic coating comprising yttria or alumina.

8. The apparatus of claim 5, wherein the plasma blocking screen is disposed a distance of between 0.5 cm and 4.0 cm from the substrate support assembly when the substrate support assembly is disposed in a processing position.

9. The apparatus of claim 5, wherein the plasma blocking screen has a thickness of between 0.01 inches and 1.0 inch.

10. The apparatus of claim 9, wherein the plasma blocking screen comprises apertures, the apertures having a diameter of between 0.01 inches and 0.25 inches.

11. The apparatus of claim 1, further comprising:
an exhaust fluidly coupled to the process region.

12. The apparatus of claim 11, wherein the exhaust is coupled to the process region opposite the remote plasma source.

13. A processing chamber apparatus, comprising:
a plate stack configured to generate a first plasma, the plate stack comprising:
a first diffuser;
a faceplate;
a ceramic ring;
a second diffuser;
a gas distribution device; and
a plasma blocking screen;
a substrate support assembly disposed opposite the plate stack;
a process region defined between the plate stack and the substrate support assembly, wherein the process region is configured to maintain generation of a second plasma; and
a remote plasma source fluidly coupled to the process region to provide a cross-flow of plasma products through the process region.

14. The apparatus of claim 13, wherein the faceplate and the second diffuser define a remote plasma region.

15. The apparatus of claim 13, wherein each of the first diffuser, the faceplate, the ceramic ring, the second diffuse, the gas distribution device, and the plasma blocking screen are coated with a ceramic coating comprising yttria or alumina.

16. The apparatus of claim 13, wherein the plasma blocking screen is disposed a distance of between 0.5 cm and 4.0 cm from the substrate support assembly when the substrate support assembly is disposed in a processing position.

17. The apparatus of claim 13, wherein the plasma blocking screen has a thickness of between 0.01 inches and 1.0 inch.

18. A processing chamber apparatus, comprising:
a plate stack configured to generate a first plasma, the plate stack comprising:
a first diffuser;
a faceplate;
a ceramic ring;
a second diffuser;
a gas distribution device; and
a plasma blocking screen;
an RF electrode electrically coupled to the first diffuser and the faceplate, wherein the first plasma is a remote plasma generated between the faceplate and the second diffuser;
a substrate support assembly disposed opposite the plate stack;
a process region defined between the plate stack and the substrate support assembly, wherein the process region is configured to maintain generation of a second plasma; and
a remote plasma source fluidly coupled to the process region to provide a cross-flow of plasma products through the process region.

19. The apparatus of claim 18, wherein each of the first diffuser, the faceplate, the ceramic ring, the second diffuse, the gas distribution device, and the plasma blocking screen are coated with a ceramic coating comprising yttria or alumina.

20. The apparatus of claim 18, wherein the plasma blocking screen is disposed a distance of between 0.5 cm and 4.0 cm from the substrate support assembly when the substrate support assembly is disposed in a processing position.
